(19) United States
(12) Patent Application Publication
(10) Pub. No.: US 2006/0105502 A1
(43) Pub. Date: May 18, 2006

(54) Assembly process

(75) Inventors: Chien Liu, Kaohsiung City (TW); Meng-Jen Wang, Pingtung County (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/259,118

(22) Filed: Oct. 27, 2005

(30) Foreign Application Priority Data
Nov. 12, 2004 (TW) 93134635

(51) Int. Cl. H01L 21/48; H01L 21/44; H01L 21/50

(52) U.S. Cl. 438/124

(57) ABSTRACT

An assembly process. The process includes providing a conductive substrate comprising opposing first and second surfaces, recessing the conductive substrate, forming a plurality of traces in the first surface, disposing an electronic device electrically connecting the traces, forming a patterned mask layer covering parts of the second surface of the conductive substrate corresponding to the traces, removing the conductive substrate not covered by the mask layer, substantially separating the traces, and forming an encapsulant covering the electrically connecting parts between the electronic device and the traces.

### BACKGROUND

The invention relates to package fabrication, and more particularly to an assembly process reducing contact areas.

Bridging problems typically occur during attachment of a package utilizing a leadframe as substrate for a PCB utilizing SMT technologies. Control of the volume of solder paste is difficult due to leadframe processing bottlenecks in processes to reduce the leadframe contact areas. Excess solder paste bridges the contact regions of the leadframe during SMT, resulting in rework or scrapping of the resulting devices, thus, the product yield and throughput is reduced.

### SUMMARY

Thus, embodiments of the inventive process, capable of substantial reduction of package contact areas to prevent the occurrence of circuit bridging during attachment of the package to a PCB.

The invention provides an assembly process. In an exemplary embodiment of an assembly process, a conductive substrate comprising opposing first and second surfaces is provided. Parts of the conductive substrate are then recessed from the first surface thereof, forming a conductive pattern comprising a plurality of traces. An electronic device is then disposed, electrically connecting the traces. A patterned mask layer is then formed covering parts of the second surface of the conductive substrate corresponding to the traces. The conductive substrate not covered by the mask layer is then removed to substantially separate the traces. Thus, the remaining conductive substrate opposite to the traces acts as contact pads corresponding thereto. The contact pads are smaller than the corresponding traces. Finally, an encapsulant is formed covering the electrically connected parts between the electronic device and the traces.

In other embodiment of an assembly process, a conductive substrate formed by laminating first and second substrates is provided. The first substrate is then partially recessed, forming a conductive pattern comprising a plurality of traces. An electronic device is then disposed, electrically connecting the traces. A patterned mask layer is then formed covering parts of the second substrate corresponding thereto. Further, the second substrate not covered by the mask layer is removed, substantially separating the traces. Thus, the remaining second substrate acts as contact pads corresponding to the traces. The contact pads are smaller than the corresponding traces. Finally, an encapsulant is formed covering the electrically connected parts between the electronic device and the traces.

### BRIEF DESCRIPTION OF THE DRAWINGS

The invention can be more fully understood by reading the subsequent detailed description in conjunction with the examples and references made to the accompanying drawings, wherein:

FIGS. 1A through 1H are cross-sections of a flow of the assembly process of a first embodiment of the invention.

FIGS. 2A through 2D are cross-sections of a flow of the assembly process of a second embodiment of the invention.

FIG. 3 is a cross-section of an exemplary resulting package of the invention.

FIGS. 4A and 4B are cross-sections of a modified flow of the assembly process of the first embodiment of the invention.

### DETAILED DESCRIPTION

The following embodiments are intended to illustrate the invention more fully without limiting the scope of the claims, since numerous modifications and variations will be apparent to those skilled in this art.

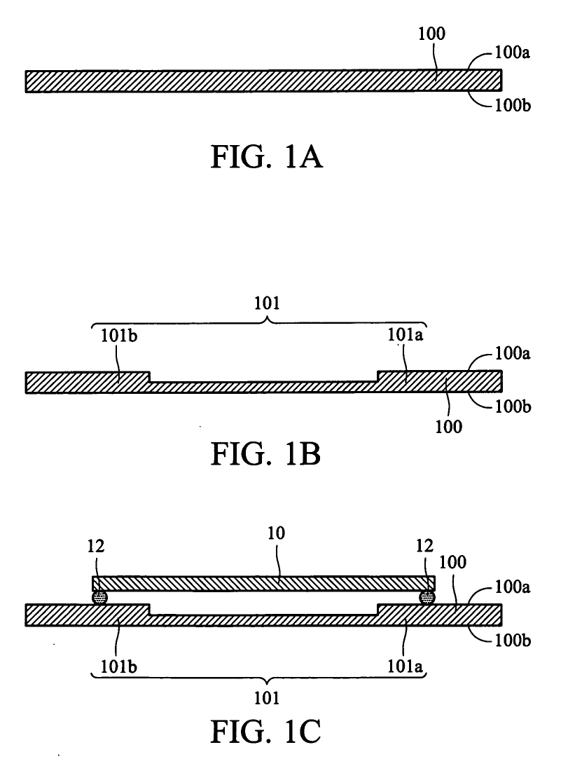

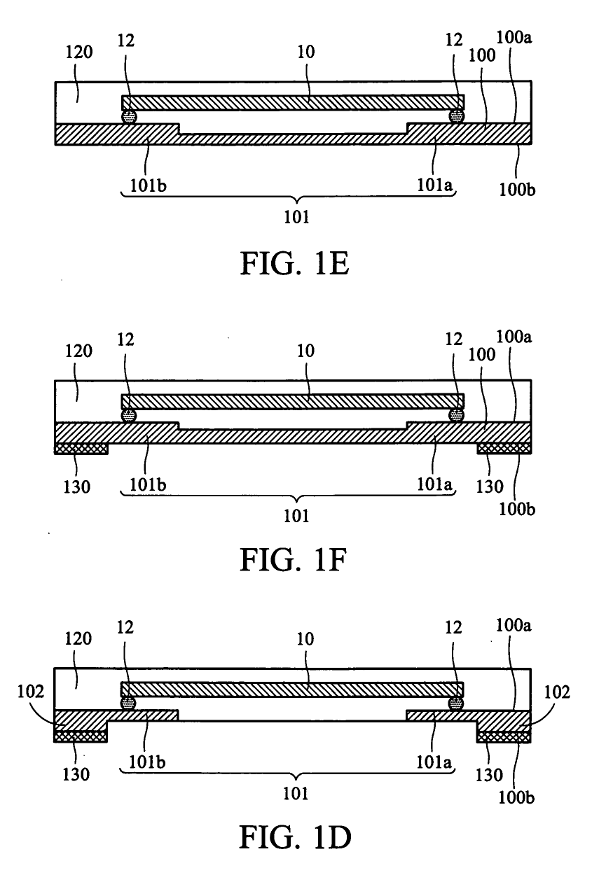

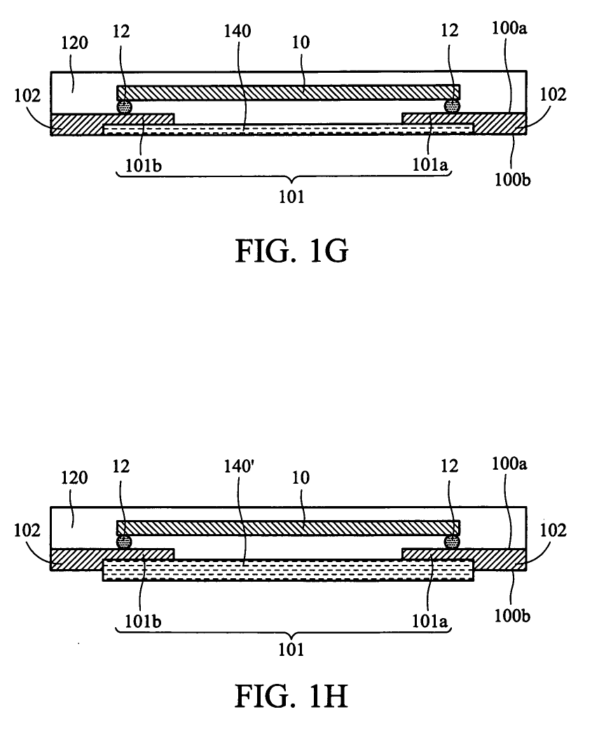

FIGS. 1A through 1H show first exemplary embodiments of the process of the invention.

As shown in FIG. 1A, a conductive substrate 200, preferably-comprising copper or aluminum, is provided. The conductive substrate 100 comprises opposing first and second surfaces 100a and 100b.

In FIG. 1B, parts of the conductive substrate 100 are recessed from the first surface 100a, forming a conductive pattern 101. The recess does not extend through the conductive substrate 100. The conductive pattern 101 comprises a plurality of traces, such as the exemplary traces 101a and 101b. The conductive substrate 100 can be recessed by a method such as photolithography, and the recess depth can be controlled by, for example, etching duration.

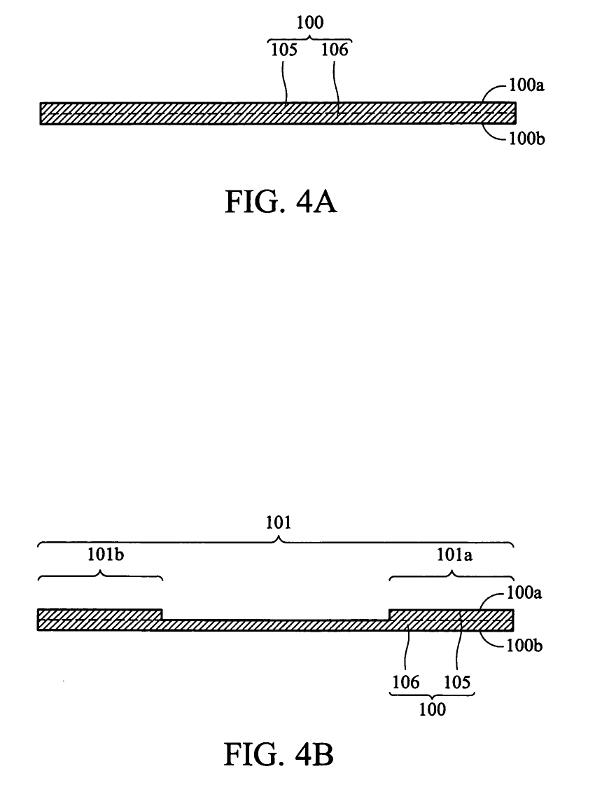

Referring to FIGS. 4A and 4B, alternatively, a first substrate 105 and a second substrate 106 can be laminated, forming the conductive substrate 100 comprising opposing first and second surfaces 100a and 100b. The first substrate 105 is then partially recessed from the first surface 100a, forming the described conductive pattern 101. At least one of the first and second substrates 105 and 106 preferably comprise copper or aluminum. The first and second substrates 105 and 106 may comprise the same or different composition.

Following that shown in FIG. 1B or 4B, an electronic device 10 is disposed, electrically connecting the traces 101a and 101b as shown in FIG. 1C. The electronic device 10 may comprise a semiconductor chip, a passive device, a packaged semiconductor chip, a packaged passive device, or a combination thereof. In this embodiment, the electronic device 10 is flipped and attached to the traces 101a and 101b via bumps 12 utilizing flip chip technology when the electronic device 10 is a semiconductor chip. Further, other bonding technologies such as wire-bonding may be utilized. Alternatively, the electronic device 10 can be attached to the traces 101a and 101b via bumps 22 utilizing SMT technologies.

In FIG. 1D, next, an encapsulant 120 is formed covering the connecting parts such as the bumps 12 between the electronic device 10 and the traces 101a, 101b. The encapsulant 120 can be formed by molding, dropping of liquid thermosetting resins, or underfill technologies. The shown encapsulant 120 is formed by molding or dropping of liquid thermosetting resins to optionally completely encapsulate the electronic device 10, or alternatively, expose parts of the electronic device 10 for thermal dissipation. The encapsulant 120 can also be formed underlying the electronic device 10 by underfilling to cover the connecting parts between the electronic device 10 and the traces 101a, 101b.

In FIG. 1E, a patterned mask layer 130 is formed covering parts of the second surface 100b of the conductive substrate 100 corresponding to the traces 101a and 101b. In an another embodiment, the patterned mask layer 130 is formed covering parts of the second substrate 106 (shown in FIG. 4B) corresponding to the traces 101a and 101b. The patterned mask layer 130 can be a resist layer, a dry film, or a solder mask. In some cases, the mask layer 130 is blanketly formed overlying the second surface 100b of the conductive substrate 100, or alternatively, the second substrate 106 (shown in FIG. 4B), followed by patterning thereof utilizing photolithography.

In FIG. 1F, the conductive substrate 100 not covered by the mask layer 130 is removed, substantially separating the traces 101a and 101b. Thus, the remaining conductive substrate 100, or alternatively, the second substrate 106 (shown in FIG. 4B) opposite to the traces 101a and 101b acts as contact pads 102 corresponding thereto. The contact pads 102 are smaller than the corresponding traces 101a and 101b. The removal procedure can be performed by wet etching or dry etching utilizing the patterned mask layer 130 as an etch mask. The size of the contact pads 102 can be controlled by adjustment of the pattern of the mask layer as desired.

Moreover, the occurrence of bridges between the contact pads 102 can be further reduced or prevented by performance of the subsequent optional steps.

In FIG. 1G, the patterned mask layer 130 is removed, followed by formation of a solder mask 140 between the contact pads, and the solder mask 140 is approximately coplanar with the contact pads 102. Alternatively, in FIG. 1H, a solder mask 140′ is formed between the contact pads, followed by removal of the patterned mask layer 130, and the solder mask 140′ projects from the contact pads 102. Further, a second encapsulant (not shown) is formed instead of the solder mask 140′.

Further, a plurality of the conductive patterns 101 can be simultaneously formed during the step shown in FIG. 1B or 4B for reducing cost and increasing throughput. A separating step such as a dicing step can be performed after one of the steps shown in FIGS. 1B through 1G to detach the processed package or unit according to each conductive pattern 101.

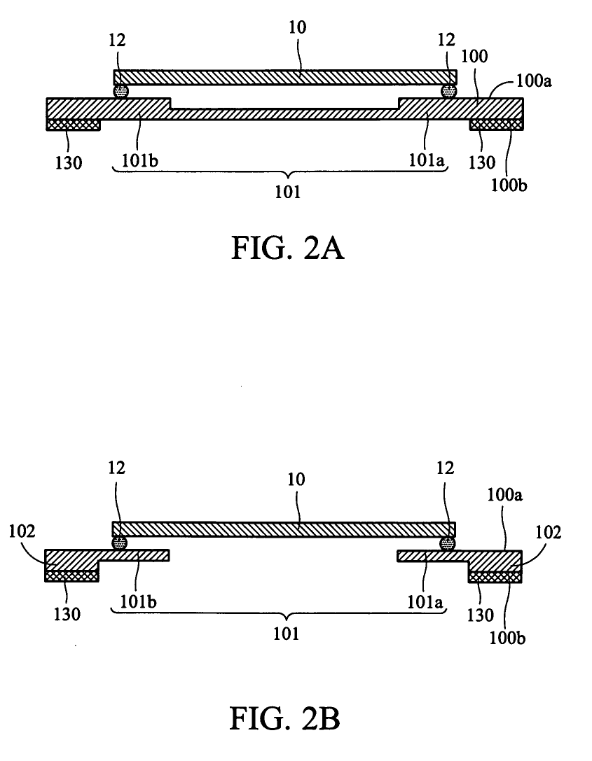

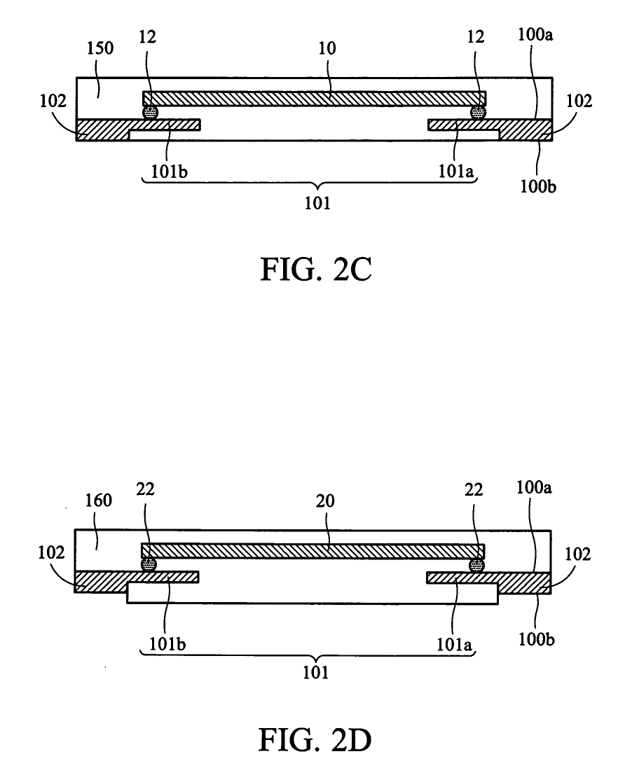

FIGS. 2A through 2D show second exemplary embodiments of the process of the invention.

In FIG. 2A, following that shown in FIG. 1C, a patterned mask layer 130 is formed covering parts of the second surface 100b of the conductive substrate 100 corresponding to the traces 101a and 101b. In an alternative embodiment, the patterned mask layer 130 formed covering parts of the second substrate 106 (shown in FIG. 4B) corresponding to the traces 101a and 101b. Details regarding the patterned mask layer 130 are the same as that shown on FIG. 1E, and thus, are omitted herefrom.

In FIG. 2B, the conductive substrate 100 not covered by the mask layer 130 is removed, substantially separating the traces 101a and 101b. Thus, the remaining conductive substrate 100, or alternatively, the second substrate 106 (shown in FIG. 4B) opposite to the traces 101a and 101b acts as contact pads 102 corresponding thereto. The contact pads 102 are smaller than the corresponding traces 101a and 101b. The removal procedure can be performed by wet etching or dry etching utilizing the patterned mask layer 130 as an etch mask. The size of the contact pads 102 can be controlled by adjustment of the pattern of the mask layer as desired.

Optionally, a second mask layer (not shown) can be formed overlying the first surface 100a of the conductive substrate beyond the conductive pattern 101 prior to the step shown in FIG. 1C. Thus, the second mask layer can protect the electronic device 10 and the conductive bumps 12 from damage during the step shown in FIG. 2B.

Next, in FIG. 2C, the patterned mask layer 130 is removed, followed by formation of an encapsulant 150, covering the connecting parts such as the bumps 12 between the electronic device 10 and the traces 101a, 101b. The encapsulant 150 can be formed by molding, dropping of liquid thermosetting resins, or underfill technologies. The shown encapsulant 150 is formed by molding or dropping of liquid thermosetting resins to optionally completely encapsulating the electronic device 10, or alternatively, expose parts of the electronic device 10 for thermal dissipation. Alternatively, the encapsulant 150 can be formed underlying the electronic device 10 by underfill to cover the connecting parts between the electronic device 10 and the traces 101a, 101b. The encapsulant 150 can be further formed between the contact pads 102, and the encapsulant 150 is approximately coplanar with the contact pads 102.

Alternatively, in FIG. 2D, following that shown in FIG. 2B, an encapsulant 160 is formed covering the connecting parts such as the bumps 12 between the electronic device 10 and the traces 101a, 101b, followed by removal of the patterned mask layer 130. The encapsulant 160 can be further formed between the contact pads 102, and the encapsulant 160 projects from the contact pads 102. Other details regarding the encapsulant 160 are the same as the encapsulant 150 shown on FIG. 2C, and thus, are omitted herefrom.

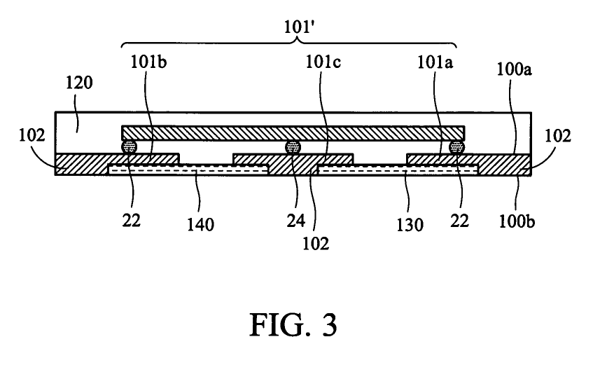

Alternatively, a conductive pattern 101′ shown in FIG. 3 can be formed during that shown in FIG. 1B or 4B utilizing the same method instead of the conductive pattern 101. The conductive pattern 101′ comprises a plurality of traces 101a, 101b and a thermal pad 101c therebetween. Other details regarding the conductive pattern 101′ are the same as the described conductive pattern 101, and thus, are omitted herefrom.

In FIG. 3, an electronic device 20 instead of the electronic device 10 is disposed, electrically connecting the traces 101a, 101b via conductive bumps 22 and thermally connecting the thermal pad 101c via a conductive bump 24 during the step shown in FIG. 1C. Other details regarding the electronic device 20 are the same as the described electronic device 10, and thus, are omitted herefrom.

In FIG. 3, the patterned mask layer 130 formed during the step shown in FIG. 1E or 2A further covers parts of the second surface 100b of the conductive substrate 100 corresponding to the thermal pad 101c. Moreover, the conductive substrate 100 not covered by the patterned mask layer 130 is removed during the step shown in FIG. 1F or 2B, and thus, the remaining conductive substrate 100 the respective traces 101a, 101b and thermal pad 101c acts as contact pads 102 less than the corresponding traces 101a, 101b and thermal pad 101c.

Steps equivalent to those shown in steps 1D and 1G/1H can be performed to complete the package shown in FIG. 3. Alternatively, the encapsulant 120 and the solder mask 140 shown in FIG. 3 can be replaced by the encapsulant 150 or 160 when performing the step shown in FIG. 2C or 2D.

The inventive process, capable of size control to the processed contact pads, reduces or prevents the occurrence of contact pad bridging during attachment of the inventive package to a PCB, improving the product yield and throughput.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. An assembly process, comprising:
providing a conductive substrate comprising opposing first and second surfaces;
recessing parts of the conductive substrate from the first surface, forming a conductive pattern comprising a plurality of traces;
disposing an electronic device electrically connecting the traces;
forming a patterned mask layer covering parts of the second surface of the conductive substrate corresponding to the traces;
removing the conductive substrate not covered by the mask layer, substantially separating the traces, wherein the remaining conductive substrate opposite to the traces acting as contact pads corresponding thereto and the contact pads are smaller than the corresponding traces; and
forming an encapsulant covering the electrically connecting parts between the electronic device and the traces, thereby forming a package comprising the encapsulant, the electronic device, the conductive pattern, and the contact pads.

2. The method as claimed in claim 1, further comprising forming a solder mask between the contact pads.

3. The method as claimed in claim 1, further comprising removing the mask layer before or after formation of the encapsulant.

4. The method as claimed in claim 3, further comprising a step of detaching the package before or after removal of the mask layer.

5. The method as claimed in claim 1, wherein the encapsulant is further formed between the contact pads, and the encapsulant is approximately coplanar with or projecting from the contact pads.

6. The method as claimed in claim 2, wherein the solder mask is approximately coplanar with or projecting from the contact pads.

7. The method as claimed in claim 1, wherein the conductive substrate comprises copper or aluminum.

8. The method as claimed in claim 1, wherein the conductive pattern further comprises a thermal pad between the traces, thermally connecting the electronic device, and the patterned mask layer covers parts of the second surface of the conductive substrate corresponding to the thermal pad.

9. The method as claimed in claim 8, further comprising forming a solder mask between the contact pads and the thermal pad.

10. The method as claimed in claim 9, wherein the solder mask is approximately coplanar with or projecting from the contact pads and the thermal pad.

11. An assembly process, comprising:
providing a conductive substrate comprising laminating first and second substrates;
partially recessing the first substrate, forming a conductive pattern comprising a plurality of traces;
disposing an electronic device electrically connecting the traces;
forming a patterned mask layer covering parts of the second substrate corresponding to the traces;
removing the second substrate not covered by the mask layer, substantially separating the traces, wherein the remaining second substrate acting as contact pads corresponding thereto and the contact pads are smaller than the corresponding traces; and
forming an encapsulant covering the electrically connecting parts between the electronic device and the traces, thereby forming a package comprising the encapsulant, the electronic device, the conductive pattern, and the contact pads.

12. The method as claimed in claim 11, further comprising forming a solder mask between the contact pads.

13. The method as claimed in claim 11, further comprising removing the mask layer before or after formation of the encapsulant.

14. The method as claimed in claim 13, further comprising a step to detach the package before or after removal of the mask layer.

15. The method as claimed in claim 11, wherein the encapsulant is further formed between the contact pads, and the encapsulant is approximately coplanar with or projecting from the contact pads.

16. The method as claimed in claim 12, wherein the solder mask is approximately coplanar with or projecting from the contact pads.

17. The method as claimed in claim 11, wherein at least one of the first and second substrates comprise copper or aluminum.

18. The method as claimed in claim 11, wherein the conductive pattern further comprises a thermal pad between the traces, thermally connecting the electronic device, and the patterned mask layer covers parts of the second substrate corresponding to the thermal pad.

19. The method as claimed in claim 18, further comprising forming a solder mask between the contact pads and the thermal pad.

20. The method as claimed in claim 19, wherein the solder mask is approximately coplanar with or projecting from the contact pads and the thermal pad.
